(19) United States
(12) Patent Application Publication
(10) Pub. No.: US 2010/0148255 A1
(43) Pub. Date: Jun. 17, 2010

(54) LATERAL HIGH-VOLTAGE MOS TRANSISTOR WITH A RESURF STRUCTURE

(76) Inventors: Felix Fuernhammer, Dresden (DE); Christoph Ellmers, Dresden (DE); Thomas Uhlig, Dresden (DE); Michael Stoisiek, Erlangen (DE)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(21) Appl. No.: 12/593,309

(22) PCT Filed: Mar. 26, 2008
(86) PCT No.: PCT/EP08/53558

§ 371 Date: Feb. 22, 2010

(30) Foreign Application Priority Data
Mar. 26, 2007 (DE) 10 2007 016 088.9
Jul. 23, 2007 (DE) 10 2007 034 802.0

(51) Int. Cl. H01L 29/78; H01L 29/06

(52) U.S. Cl. 257/342; 257/343; 257/E29.256

(57) ABSTRACT

For achieving an enhanced combination of a low on-resistance at a high break-through voltage a lateral high-voltage MOS transistor comprises a plurality of doped RESURF regions of the first conductivity type within the drift region, wherein the doped RESURF regions are separated from each other by drift region sections in a first lateral direction (y), which is parallel to a substrate surface and is orthogonal to a connecting line from the source region to the drain region, and also in a depth direction, which is orthogonal to the substrate surface, such that in each of said two directions an alternating arrangement of regions of the first and second conductivity types is provided.

### CROSS REFERENCE TO RELATED APPLICATION

The application is a U.S. National Stage Application of International Application of PCT/EP2008/1053558 filed Mar. 26, 2008, which claims priority of German Patent Application No. 10 2007 016 088.9 filed Mar. 26, 2007 and German Patent Application No. 10 2007 034 802.0 filed Jul. 23, 2007, the disclosures which are incorporated by reference in their entirety.

### BACKGROUND OF THE DISCLOSURE

Lateral high-voltage MOS transistors including an n-conductive channel are typically fabricated as DMOS transistors, whose topology of doped zones corresponds to those of a “double-diffused” transistor, wherein a drain region is of the same conductivity type as a well doping, i.e., of n-type conductivity type. Lateral high-voltage MOS transistors including a p-conductive channel are typically fabricated as a drain extension transistor, in which drain and drift regions are of inverse conductivity type compared to the n-well. Both transistor types will commonly be addressed in the present application with the term lateral high-voltage MOS transistor.

It is known from US 2003/0193067 A1 to use a so-called double RESURF structure in lateral high-voltage MOS transistors at high electric voltages. RESURF is the abbreviation of the English term “reduced surface field”.

A double RESURF structure comprises in the drift region or below a drain extension region of a lateral high-voltage MOS transistor a doped region of a conductivity type that is inverse with respect to that of the drift region. For example, for an n-conductive drift region the doped region of the double RESURF structure incorporated therein is p-conductive. Typically, the doped region has a dopant concentration of the same magnitude as the drift region.

Upon applying a voltage at the drain electrode of the lateral high-voltage MOS transistor a depletion zone is generated by means of the double RESURF structure, which extends along the boundary between the drift region and a substrate region positioned below and having the inverse conductivity type. A further depletion zone is formed between the doped region incorporated in the drift region and the drift region itself.

In this way a full depletion of charge carriers in the drift region is caused by these two inversely biased pn junctions, thereby resulting in a desired increase of the break-through voltage of the lateral high-voltage MOS transistor. At the same time the incorporation of the doped region into the drift region the concentration of charge carriers may be increased in the drift region, thereby reducing the on-resistance of the lateral high-voltage MOS transistor; since for increasing the break-through voltage for the inversely biased state only the incorporated net doping of the drift region and of the doped region incorporated therein is essential. For these purposes, however, the incorporated doped regions compensate for the dopant concentration of the drift region. Therefore, relatively high dopant concentrations may be used in the drift region, thereby resulting in an increase of the drift region's conductivity and thus in a reduction of the Rₒₙ without reducing the break-through voltage.

From US 2003/0193067 it is further known to incorporate a plurality of column-shaped doped regions into the drift region in order to further increase the dopant concentration of the drift region in this manner, on the one hand, and, on the other hand, to allow at the same time to increase the break-through voltage.

It is desirable to further reduce the on-resistance without concurrently reducing the break-through voltage in an undesirable manner.

The technical problem of the present invention is to provide a lateral high-voltage MOS transistor that enables to obtain a particularly low on-resistance.

### SUMMARY OF THE INVENTION

A lateral high-voltage MOS transistor of the present invention comprises
a semiconductor substrate of a first conductivity type;
a doped body region of the first conductivity type at a substrate surface of the semiconductor substrate;
a source region of a second conductivity type that is inverse to the first conductivity type, which source region is embedded in the doped body region at the substrate surface;
a channel region formed at the substrate surface between the source region and an edge of the doped body region;
a gate electrode above the channel region, which gate electrode is electrically insulated from a gate isolation region;
a drift region of the second conductivity type, which is located in an area of the semiconductor substrate adjacent to the channel region;
a drain region of the second conductivity type adjacent to the drift region; and
a plurality of doped RESURF regions of the first conductivity type In the drift region, wherein the doped RESURF regions are separated from each other by drift region sections in a first lateral direction (y), which is parallel to the substrate surface and which is orthogonal to a line connecting the source region and the drain region, and also in a depth direction (z), which is orthogonal to the substrate surface, such that in each of said two directions an alternating arrangement of regions of the first and second conductivity types, respectively, is provided. For reasons of simplified language the first lateral direction will herein be referred to as length direction.

The lateral high-voltage MOS transistor of the present invention represents an alternative structure compared to conventional double or multi RESURF structures, which alternative structure in its most simple form achieves an improved combination of on resistance and break-through voltage compared to US 2003/0193067. In each of said two directions an alternating arrangement of regions of the first and second conductivity types is provided.

The lateral high-voltage MOS transistor of the present invention thus has an alternating arrangement of doped RESURF regions along the depth direction, that is, taken in a section plane that is orthogonal to a main flow direction of the majority charge carriers between the source region and the drain region. This allows a further increase of the dopant concentration in the doped RESURF regions and in the drift region, thereby enabling a reduction of the on-resistance without concurrently reducing the break-through voltage. Since for the amount of the break-through voltage the integrated net dopant concentration is relevant. The integrated net dopant concentration, however, is not increased by the inventive arrangement as p-conductive and n-conductive regions compensate each other upon integration. If p- and n-conductive regions have the same amount of dopant concentration in the section plane the net dopant concentration in the section plane is null, thereby enabling a particularly high break-through voltage.

In the following embodiments of the inventive method will be described. The embodiments may be combined with each other unless otherwise explicitly stated.

In first embodiment of two alternatives a part of the doped RESURF regions or all of the doped RESURF regions extend throughout the entire drift region in a second lateral direction (x), which is parallel to the substrate surface and to a line connecting source and drain. For sake of a simplified language the second lateral direction is referred to a transverse direction.

In an embodiment that is alternative to this one a part of the doped RESURF regions or all of the doped RESURF regions are additionally separated in the transverse direction by drift region sections such that also in the transverse direction an alternating arrangement of regions of the first and second conductivity types is provided. The alternating arrangement is configured such that upon application of a supply voltage at the source and drain regions a continuous current path for majority charge carriers is provided through the drift region. In this second alternative embodiment the extensions and distances of the doped RESURF regions in the lateral directions and in the depth direction are selected such that upon application of a supply voltage at the source and drain regions the majority charge carrier current (drift current) flows in the drift region. If source, drain and drift regions are n-conductive then the continuous current path through the alternating arrangement is thus an n-conductive current path.

US 2003/0193067 describes an alternating arrangement of drift regions and RESURF regions in two lateral directions, but not in the depth direction. The present embodiment complements the above-described advantages of the inventive structure by the advantages of the structure known from US 2003/0193067. By means of the arrangement of the present embodiment the dopant concentrations in the drift region of the second conductivity type and in the doped RESURF regions of the first conductivity type may be further increased, since the inventive arrangement of the doped RESURF regions enables a full depletion of the drift region at the RESURF structure for supply voltages that correspond to supply voltages of conventional lateral high-voltage MOS transistors having a lower dopant concentration.

Depending on the selected arrangement of doped RESURF regions the majority charge carrier current flows through the drift region in a substantially linear manner exclusively in one plane, or parallel in several planes. The arrangement may also be selected such that the current flow is not linear. For instance, the current flow may follow a sort of wavy line that extends between two or more planes. Although such a current path is longer compared to a linear current path and also increases the on-resistance, on the other hand, the dopant concentration in the drift region may be further increased. Also in this embodiment a linear line extending between the source region and the drain region is considered as the main current flow direction.

Also a combination of the alternative first and second embodiments is contemplated in the sense that the drift region is configured in part in accordance with the first alternative embodiment and in part in accordance with the second alternative embodiment.

In embodiments the doped RESURF regions and the drift region have a dopant concentration between 10¹⁶ and 10¹⁸ cm⁻³. In one embodiment this dopant concentration is between 10¹⁷ and 10¹⁸ cm⁻³, in another embodiment between 3×10¹⁷ and 1×10¹⁸ cm⁻³, in a further embodiment between 5×10¹⁷ and 1×10¹⁸ cm⁻³. In a further embodiment this dopant concentration is 1×10¹⁸ cm⁻³.

In a further lateral high-voltage MOS transistor the alternating arrangement of region of the first and second conductivity types—taken in a longitudinal sectional view—comprises rows extending in the length direction (y) and columns extending in the depth direction (z), in which the doped RESURF regions and the drift region sections are arranged in an alternating manner. A longitudinal sectional view illustrates the structure of the high-voltage MOS transistor in the length direction (y) and in the depth direction (z).

In a further lateral high-voltage MOS transistor the alternating arrangement of regions of the first and second conductivity types additionally or alternatively comprises—taken in a cross-sectional view—rows extending in the transverse direction and columns extending in the depth direction, in which doped RESURF regions and drift region sections are provided in an alternating manner. A cross-sectional view illustrates the structure of the high-voltage MOS transistor in a transverse direction (x) and in the depth direction (z).

In a further lateral high-voltage MOS transistor there are arranged—as viewed in a cross-section view and counted in the transverse direction (x)—three or more doped RESURF regions in each row within the drift region. In a further variant of this embodiment of the lateral high-voltage MOS transistor six or more doped RESURF regions are provided within the drift region in each row. In this embodiment ten or more doped RESURF regions may also be arranged in each row within the drift region.

In one embodiment three or more doped RESURF regions of the first conductivity type are arranged in the drift region in each column—in a cross-sectional view and counted in the depth direction (z). In one variant of this embodiment six or more doped RESURF regions are provided in the drift region in each column. In a further variant there are provided even ten or more doped RESURF regions in each column within the drift region.

In a further embodiment the lateral high-voltage MOS transistor has—taken in a longitudinal sectional view and counted in the length direction (x)—three or more doped RESURF regions arranged in the drift region. In particular embodiments six or more doped RESURF regions, or even ten or more doped RESURF regions may be provided.

In one embodiment the doped RESURF regions have the same pitch in one lateral direction, and, where compatible with a distribution in both lateral directions, have the same pitch in both lateral directions. In one embodiment additionally or alternatively the doped RESURF regions also have the same pitch in the depth direction. An extension of the doped RESURF regions in a respective direction between two adjacent doped RESURF regions is preferably less than or equal to the pitch between two adjacent doped RESURF regions of the first conductivity type in the respective direction.

Alternatively, each of the doped RESURF regions has a fix first and second lateral pitch, respectively, in the two lateral directions, wherein the first and second lateral pitches are different.

In a lateral high-voltage MOS transistor the doped RESURF regions are located below a trench filled with an electrically insulating material in a direction that points to the interior of the substrate. In one embodiment the trench is formed according to a shallow trench technology, in another embodiment according to a LOCOS technology.

In some embodiments each of the doped RESURF regions and the drift region sections arranged therebetween are located within cuboid-shaped, alternatively cube-shaped, volume portions that are adjacent to each other and have the same side length within the entire drift region, wherein it is to be appreciated, as explained above, that the current flow through the drift region is not discontinued by the arrangement of the doped RESURF regions during operation. In a further embodiment the doped RESURF regions are either cylinder-shaped or substantially cylinder-shaped, in the latter case, for instance, pear-shaped or drop-shaped.

Preferably, a respective dopant concentration for obtaining the respective conductivity type in the doped region of the first conductivity type and in the drift region of the second conductivity type is the same or is approximately the same.

A respective dopant concentration for obtaining the respective conductivity type, in the doped region of the first conductivity type and in the drift region of the second conductivity type, may be for instance between 10¹⁶ and 10¹⁸ cm⁻³. In a circular cylinder-shaped configuration of an n-conductive channel that is surrounded by a tube wall and has a radius of 1 μm a highest allowable doping of the n-conductive cylinder is 1×10¹⁷ cm⁻³. If the radius is 5 μm then the maximum allowable dopant concentration is 0.2×10¹⁷ cm⁻³.

Typically, p-conductive substrates in the form of wafers are used for high-voltage MOS transistors. In this case, the transistor is formed, as described before, in an n-conductive well. This arrangement is, however, not mandatory.

### BRIEF DESCRIPTIONS OF THE DRAWINGS

In the following an illustrative embodiment is described with reference to the drawings. In the drawings:

FIG. 1 shows a schematic top view of a lateral high-voltage MOS transistor of one embodiment, and

FIG. 2 shows a schematic longitudinal sectional view of the lateral high-voltage MOS transistor along the section II-II.

### DETAILED DESCRIPTION OF THE DISCLOSURE

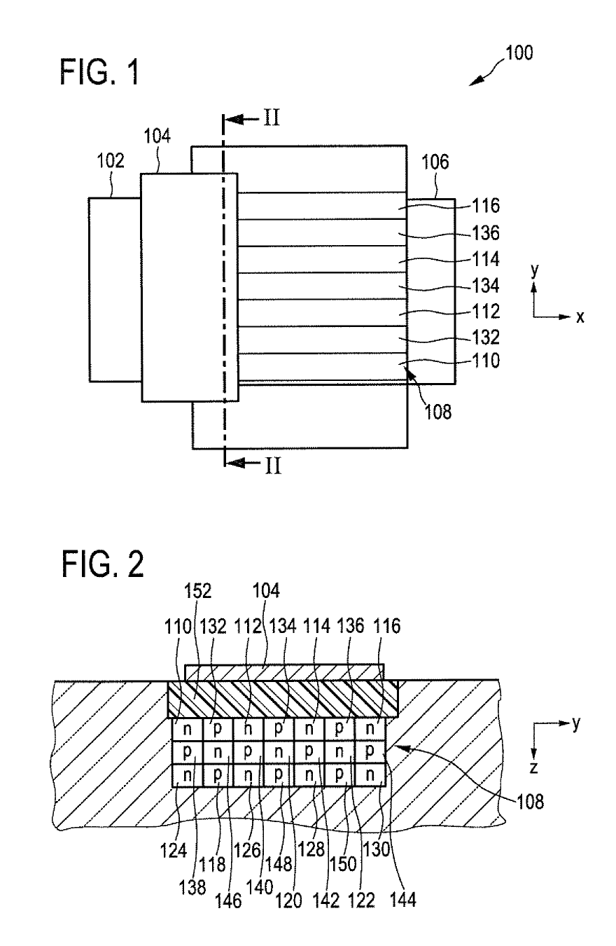

FIG. 1 illustrates a schematic top view of a lateral high-voltage MOS transistor 100 comprising a multi RESURF structure.

The lateral high-voltage MOS transistor 100 includes a highly doped n⁺-source region 102 and a highly doped n⁺-drain region 106 and an n-drift region that includes the multi RESURF structure. The first conductivity type according to language of the claims thus corresponds in this embodiment to the p-conductivity and the second conductivity type corresponds to the n-conductivity.

Moreover, a gate electrode 104 is illustrated that overlaps with the drift region 108 and the multi RESURF structure but that does not overlap with the source region 102. The source region 102 is embedded in a doped body region of the first conductivity type that laterally extends from the drift region 108 to the source region 102 and beyond. The doped body region is not shown in FIG. 1.

In one embodiment the lateral high-voltage MOS transistor is embedded in a doped well of the second conductivity type and is implemented on a substrate of the first conductivity type. The well is not shown in the figures.

By means of a coordinate system having an x axis and a y axis two spatial directions are indicated on the surface of the substrate. The y direction is referred to as a length direction and the x direction is referred to as a transverse direction. The drift region 108 extends from the drain region 106 to and below the gate electrode 104. The drift region 108 includes approximately cylinder shaped doped RESURF regions 132 to 136 of the first conductivity type, which extend along the transverse direction, and includes drift region sections 110 to 116 in between that are also approximately cylinder-shaped.

The doped RESURF regions and the drift region sections extend across the entire drift region in the transverse direction. In the length direction there are drift region sections 110 to 116 and doped RESURF regions 132 in an alternating manner. With this structure the multi RESURF structure is formed in the drift region of the lateral high-voltage MOS transistor. The drift region sections 110 to 116 have the second conductivity type and the doped RESURF regions have the first conductivity type, i.e., they are p-conductive. In one embodiment the doped RESURF regions and the drift region sections are arranged such that a current flows between the source region 102 and the drain region 106 upon concurrently driving the gate electrode 104.

FIG. 2 illustrates a longitudinal sectional view of the lateral high-voltage MOS transistor along the section II-II of FIG. 1.

A coordinate system having a y axis and a z axis is illustrated. The y direction corresponds to the y direction of FIG. 1 and the z direction corresponds to a direction from the substrate surface to the depth of the substrate.

Among others, there is illustrated the drift region 108 in which the multi RESURF structure is implemented. Above the drift region there is located an isolation region 152 that extends to the substrate surface. The isolation region may consist of silicon dioxide or any other appropriate insulator. The gate electrode 104 is formed above the isolation region on the surface of the substrate.

The multi RESURF structure in the drift region 108 includes the drift region sections 110 to 130, which are n-doped in this embodiment, and the doped RESURF regions 132 to 150, which are p-doped in this embodiment. This is indicated in FIG. 2 by the letters n and p. The drift region sections 110 to 130 and the doped RESURF regions 132 to 150 are arranged in an alternating manner in rows in the z direction, i.e., in the depth direction, and in an alternating manner in columns in the y direction.

In this embodiment the lateral high-voltage MOS transistor comprises a multi RESURF structure, formed by the doped RESURF regions and the drift region sections 110 to 130, alternating in the length direction, i.e., in the y direction, and also in the depth direction, i.e., in the z direction. In this embodiment the drift region sections and the doped RESURF regions are illustrated in a rectangular shape in this figure, in another embodiment, however, they may be circular in the longitudinal section and may have circular cylindric in the x direction. Appropriate dopants for p-doped areas are, for example, boron, and for n-doped areas phosphorous P or arsenic As.

In the following a list of reference signs is given for explaining features of the lateral high-voltage MOS transistor of FIGS. 1 and 2 of this embodiment.
100 lateral high-voltage MOS transistor
102 source region
104 gate electrode
106 drain region
108 drift region
110 to 130 drift region sections, each approximately cylinder-shaped
132 to 150 doped RESURF regions, each approximately cylinder-shaped
152 isolation region
x transverse direction
y length direction
z depth direction

1. A high-voltage DMOS transistor comprising
a semiconductor substrate of a first conductivity type;
a doped body region of the first conductivity type at a substrate surface of the semiconductor substrate;
a source region of a second conductivity type that is inverse to the first conductivity type, which source region is embedded in the doped body region at the substrate surface;
a channel region formed at the substrate surface between the source region and an edge of the doped body region;
a gate electrode formed above the channel region electrically insulated from a gate isolation region;
a drift region of the second conductivity type, which is located in an area of the semiconductor substrate that is adjacent to the channel region and faces away from the source region;
a drain region of the second conductivity type adjacent to the drift region; and
a plurality of doped RESURF regions of the first conductivity type In the drift region, wherein the doped RESURF regions are separated from each other by drift region sections in a first lateral direction (y), which is parallel to the substrate surface and which is orthogonal to a line connecting the source region and the drain region, hereinafter the length direction, and also in a depth direction (z), which is orthogonal to the substrate surface, such that in each of said two directions an alternating arrangement of regions of the first and second conductivity types, respectively, is provided.

2. The high-voltage DMOS transistor of claim 1, in which either a part of the doped RESURF regions or all of the doped RESURF regions extend throughout the entire drift region in a second lateral direction (x), hereinafter the transverse direction, which is parallel to the substrate surface and to a connecting line from the source region to the drain region.

3. The high-voltage DMOS transistor of claim 1, in which either a part of the doped RESURF regions or all of the doped RESURF regions are additionally separated in a second lateral direction (x) that is parallel to the substrate surface and to a connecting line from the source region to the drain region, hereinafter the transverse direction, by drift region sections such that also in the transverse direction an alternating arrangement of regions of the first and second conductivity types is provided and that upon application of a supply voltage at the source and drain regions a continuous current path for majority charge carriers is provided through the drift region.

4. The high-voltage DMOS transistor of claim 3, in which extensions and pitches of the doped RESURF regions in the lateral directions and in the depth direction are selected such that a drift current flows upon applying a supply voltage to the source and drain regions.

5. The high-voltage DMOS transistor of claim 2, in which the alternating arrangement of regions of the first and second conductivity types in a longitudinal sectional view has rows extending in the length direction (y) and columns extending in the depth direction (z), in which the doped RESURF regions and the drift region sections are arranged in an alternating manner.

6. The high-voltage DMOS transistor of claim 3, in which the alternating arrangement of regions of the first and second conductivity types in a cross sectional view has rows extending in the transverse direction (x) and columns extending in the depth direction, in which the doped RESURF regions and the drift region sections are arranged in an alternating manner.

7. The high-voltage DMOS transistor of claim 3, in which three or more doped RESURF regions are arranged in each row within the drift region when viewed in a cross-section and counted in the transverse direction (x).

8. The high-voltage DMOS transistor of claim 7, wherein six or more doped RESURF regions are arranged within the drift region in each row when viewed in a cross-section and counted in the transverse direction (x).

9. The high-voltage DMOS transistor of claim 8, wherein three or more doped RESURF regions are arranged in each row within the drift region when viewed in a cross-section and counted in the transverse direction (x).

10. The high-voltage DMOS transistor of claim 2, in which three or more doped RESURF regions are arranged in each column within the drift region when viewed in a cross-section and counted in the depth direction (z).

11. The high-voltage DMOS transistor of claim 10, in which six or more doped RESURF regions are arranged in each column within the drift region when viewed in a cross section and counted in the depth direction (z).

12. The high-voltage DMOS transistor of claim 11, in which ten or more doped RESURF regions are arranged in each column within the drift region when viewed in a cross section and counted in the depth direction (z).

13. The high-voltage DMOS transistor of claim 1, in which three or more doped RESURF regions are arranged in the drift region when viewed in a longitudinal section and counted in the length direction (x).

14. The high-voltage DMOS transistor of claim 13, in which six or more doped RESURF regions are arranged in the drift region when viewed in a longitudinal section and counted in the length direction (x).

15. The high-voltage DMOS transistor of claim 13, in which ten or more doped RESURF regions are arranged in the drift region when viewed in a longitudinal section and counted in the length direction (x).

16. The high-voltage DMOS transistor of claim 2, in which the doped RESURF regions have the same pitch from in one of the lateral direction or in the depth direction.

17. The high-voltage DMOS transistor of claim 16, in which an extension of the doped RESURF regions of the respective direction is less or equal to the pitch between two adjacent doped RESURF regions of the first conductivity type in the respective direction.

18. The high-voltage DMOS transistor of claim 3, in which the doped RESURF regions have the same pitch in both lateral directions.

19. The high-voltage DMOS transistor of claim 3, in which the doped RESURF regions have in a each of the two lateral directions a respective first pitch and a respective second pitch, wherein the first pitch differs from the second pitch.

20. The high-voltage DMOS transistor of claim 1, in which the doped RESURF regions are arranged below a trench filled with an electrically insulating material.

21. The high-voltage DMOS transistor of claim 20, in which the trench is formed according to a shallow trench technology.

22. The high-voltage DMOS transistor of claim 3, in which each of the doped RESURF regions and the drift region sections arranged therebetween are located within cuboid-shaped volume portions that are adjacent to each other, wherein different coboid-shaped volume portions have the same side length.

23. The high-voltage DMOS transistor of claim 1, in which each of the doped RESURF regions and the drift region sections arranged therebetween are located within cube-shaped volume portions that are adjacent to each other and have the same side length within the entire drift region.

24. The high-voltage DMOS transistor of claim 3, in which the doped RESURF regions have an approximately the shape of one of a cube, a sphere, a pear and an oval.

25. The high-voltage DMOS transistor of claim 1, in which the doped RESURF regions are either cylinder-shaped or substantially cylinder-shaped, in the latter case, pear-shaped or drop-shaped when viewed in a longitudinal section.

26. The high-voltage DMOS transistor of claim 1, in which a respective dopant concentration for obtaining the respective conductivity type in a respective doped RESURF region of the first conductivity type and in the drift region of the second conductivity type is the same.

27. The high-voltage DMOS transistor of claim 1, in which a respective dopant concentration for obtaining the respective conductivity type in the doped RESURF region and in the drift region is between 10¹⁶ and 10¹⁸ cm⁻³.

28. The high-voltage DMOS transistor of claim 1, in which a dopant concentration in the doped RESURF region and in the drift region is greater than or equal to 2×10¹⁷ cm⁻³.
